(19) United States
(12) Patent Application Publication
(10) Pub. No.: US 2015/0173196 A1
(43) Pub. Date: Jun. 18, 2015

(54) CAPACITOR EMBEDDED SUBSTRATE AND MANUFACTURING METHOD THEREOF

(71) Applicant: SAMSUNG ELECTRO-MECHANICS CO., LTD., Suwon-Si (KR)

(72) Inventors: Yong-Seok CHOI, Suwon-Si (KR); Doo-Yun CHUNG, Suwon-Si (KR); Kwang-Jae OH, Suwon-Si (KR); Dae-Hyeong LEE, Suwon-Si (KR)

(73) Assignee: SAMSUNG ELECTRO-MECHANICS CO., LTD., Suwon-Si, Gyeonggi-Do (KR)

(21) Appl. No.: 14/334,492

(22) Filed: Jul. 17, 2014

(30) Foreign Application Priority Data
Dec. 17, 2013 (KR) 10-2013-0157437

(51) Int. Cl. H05K 1/18; H05K 13/00; H05K 1/11; H01G 4/12; H05K 1/03

(52) U.S. Cl. CPC H05K 1/185; H01G 4/1209; H05K 1/0306; H05K 1/115; H05K 13/00; H05K 2201/09645

(57) ABSTRACT

A capacitor embedded substrate and a manufacturing method thereof are disclosed. The capacitor embedded substrate in accordance with an embodiment of the present invention includes: a ceramic layer having a first circuit included therein; a receiving grooved formed on one surface of the ceramic layer; a capacitor being inserted in the receiving groove; a polymer layer being laminated on the ceramic layer in such a way that the capacitor is embedded in the receiving groove and comprising a second circuit electrically connected with the first circuit; and a via electrode being connected with the capacitor by penetrating the polymer layer.

### CROSS-REFERENCE TO RELATED APPLICATIONS

This application claims the benefit of Korean Patent Application No. 10-2013-0157437, filed with the Korean Intellectual Property Office on Dec. 17, 2013, the disclosure of which is incorporated herein by reference in its entirety.

### BACKGROUND

1. Technical Field

The present invention relates to a capacitor embedded substrate and a manufacturing method thereof.

2. Background Art

Ceramic substrates can be fabricated by LTCC (Low Temperature Co-fired Ceramics) or HTCC (High Temperature Co-fired Ceramics). With LTCC, ceramic adhesive material is baked at a temperature of 1000° C. or below, and with HTCC, ceramic adhesive material is baked at a temperature of 1200° C. or above.

The ceramic substrate can be used as a STF (Space Transformer) substrate of a probe card, which is used for inspection of semiconductor wafers. The inspection is for checking for any wafer defect and removing the defective portion of the wafer. The probe card functions as an interface between the inspecting equipment and the wafer in the inspection.

The related art of the present invention is disclosed in Korea Patent Publication No. 10-2012-0095657 (SPACE TRANSFORMER SUBSTRATE FOR PROBE CARD: laid open on Aug. 29, 2012).

### SUMMARY

The present invention provides a capacitor embedded substrate in which a capacitor is embedded by a receiving groove of a ceramic layer and a polymer layer.

An aspect of the present invention provides a capacitor embedded substrate, which includes: a ceramic layer having a first circuit included therein; a receiving grooved formed on one surface of the ceramic layer; a capacitor being inserted in the receiving groove; a polymer layer being laminated on the ceramic layer in such a way that the capacitor is embedded in the receiving groove and comprising a second circuit electrically connected with the first circuit; and a via electrode being connected with the capacitor by penetrating the polymer layer.

The capacitor embedded substrate can further include a resin material being filled in the receiving groove so as to fix the capacitor.

The resin material can cover an upper surface of the capacitor, and the via electrode can penetrate the resin material.

The receiving groove can be formed in such a way that a depth thereof is smaller than a thickness of the capacitor.

The polymer layer can include a plurality of layers, and the via electrode can penetrate the plurality of layers perpendicularly to the polymer layer.

The capacitor embedded substrate can further include a pad electrode formed on an upper surface of the polymer layer so as to be connected with the via electrode.

The polymer layer can be formed in such a way that a thickness thereof is smaller than a thickness of the ceramic layer.

The receiving groove can be arranged on an inside of the ceramic layer.

The polymer layer can include polyimide.

Another aspect of the present invention provides a method of manufacturing a capacitor embedded substrate that includes: forming a receiving groove on one surface of a ceramic layer, the ceramic layer having a first circuit included therein; inserting a capacitor in the receiving groove; laminating a polymer layer on the ceramic layer in order to embed the capacitor in the receiving groove, the polymer layer comprising a second circuit electrically connected with the first circuit; and forming a via electrode by penetrating the polymer layer, the via electrode being electrically connected with the capacitor.

The method can further include, prior to forming the receiving groove on the ceramic layer: forming the ceramic layer by laminating ceramic sheets; and baking the ceramic layer.

The method can further include, before or after inserting the capacitor in the receiving groove, filling in the receiving groove with a resin material.

In the step of forming the receiving groove, the receiving groove can be formed in such a way that a depth thereof is greater than a thickness of the capacitor, and in the step of forming the via electrode, the via electrode can penetrate the resin material covering an upper surface of the capacitor.

In the step of laminating the polymer layer on the ceramic layer, the polymer layer can be formed in such a way that a thickness thereof is smaller than a thickness of the ceramic layer.

The polymer layer can include a plurality of layers, and in the step of forming the via electrode, the via electrode can penetrate the plurality of layers perpendicularly to the polymer layer.

The forming of the via electrode can include: forming a via hole in the polymer layer in such a way that an external electrode of the capacitor is exposed; and forming a conductor in the via hole.

The forming of the conductor can include: forming a seed layer on the polymer layer so as to cover an inner portion of the via hole; forming a resist on the seed layer; forming an opening in the resist in such a way that the seed layer is exposed; forming a plating layer in the opening; and removing the seed layer and the resist.

The method can further include, after forming the via electrode, forming a pad electrode on an upper surface of the polymer layer so as to be connected with the via electrode.

According to certain embodiments of the present invention, the capacitor can be readily embedded in the substrate, and noise can be reduced when electric power is supplied by the embedded capacitor.

### BRIEF DESCRIPTION OF THE DRAWINGS

FIG. 1 shows a capacitor embedded substrate in accordance with an embodiment of the present invention.

FIGS. 2 and 3 show capacitor embedded substrates in accordance with various embodiments of the present invention.

FIG. 4 is a flow diagram showing a method of manufacturing a capacitor embedded substrate in accordance with an embodiment of the present invention.

FIGS. 5 to 15 show processes for the method of manufacturing a capacitor embedded substrate in accordance with an embodiment of the present invention.

### DETAILED DESCRIPTION

Hereinafter, a capacitor embedded substrate and a method of manufacturing the same in accordance with certain embodiments of the present invention will be described in detail with reference to the accompanying drawings. In describing the present invention with reference to the accompanying drawings, any identical or corresponding elements will be assigned with same reference numerals, and no redundant description thereof will be provided.

Terms such as “first” and “second” can be used in describing various elements, but the above elements shall not be restricted to the above terms. The above terms are used only to distinguish one element from the other.

When one element is described to be “coupled” to another element, it does not refer to a physical, direct contact between these elements only, but it shall also include the possibility of yet another element being interposed between these elements and each of these elements being in contact with said yet another element.

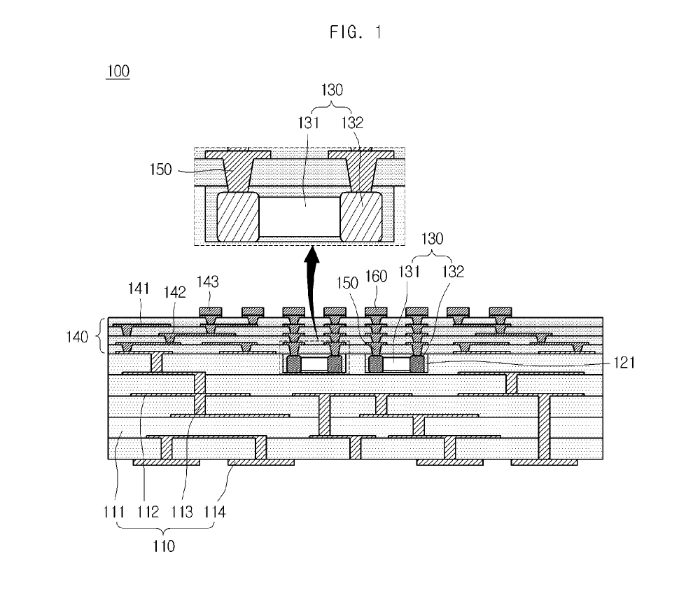

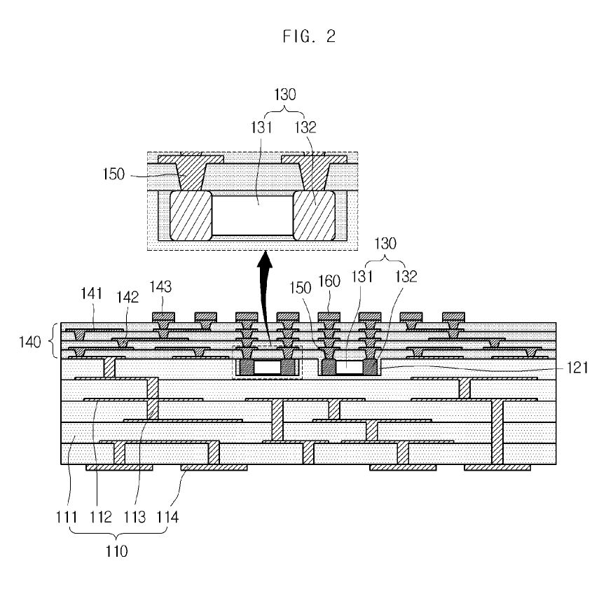

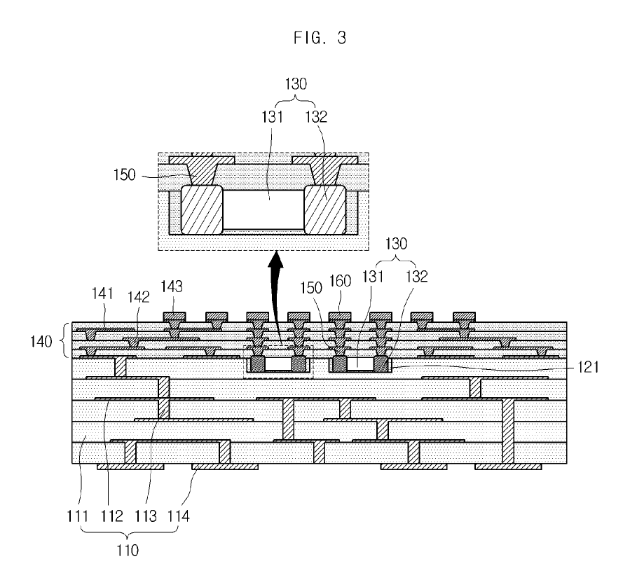

FIG. 1 shows a capacitor embedded substrate in accordance with an embodiment of the present invention, and FIGS. 2 and 3 show capacitor embedded substrates in accordance with various embodiments of the present invention.

Referring to FIG. 1, a capacitor embedded substrate 100 in accordance with an embodiment of the present invention can include ceramic layer 110, receiving groove 120 (see FIG. 6), capacitor 130, polymer layer 140 and via electrode 150, and can further include pad electrode 160.

The ceramic layer 110 can be constituted with ceramic sheets 111 and can be a laminate of a plurality of ceramic sheets 111. The ceramic layer 110 can include a first circuit 112. The ceramic layer 110 can have a thickness of 5 mm to 6 mm. Moreover, the first circuit 112 can be made of silver (Ag) or tungsten (W).

The receiving groove 120 can be formed on one surface of the ceramic layer 110. The receiving groove 120 can be formed by laser or drill. The receiving groove 120 can be formed inside the ceramic layer 110 and can be provided in plurality.

The capacitor 130 can be inserted in the receiving groove 120. The capacitor 130 can include dielectric layer 131, internal electrode and external electrode 132. The capacitor 130 can be inserted in the receiving groove 120 to be spaced from an inside wall of the receiving groove 120.

In such a case, resin material 121 can be filled in the receiving groove 120 so that the capacitor 130 can be fixed. The resin material 121 can include polyimide. Polyimide is chemically stable and durable and thus can be a preferable material for fixing the capacitor 130.

The receiving groove 120 can be formed in such a way that a depth thereof is greater than a thickness of the capacitor 130. In such a case, as illustrated in FIG. 1, the resin material 121 can cover an upper surface of the capacitor 130.

The polymer layer 140 can be an insulating layer made of polymer and can include a plurality of insulating layers. The polymer layer 140 can include a second circuit 141. The second circuit 141 can be electrically connected with the first circuit 112 of the ceramic layer 110. Since fine patterns can be formed on the polymer layer 140, a greater number of circuits can be realized with a given number of ceramic layers 110.

Formed on the ceramic layer 110 can be a first via 113, which is electrically connected with the first circuit 112, and formed on the polymer layer 140 can be a second via 142, which is electrically connected with the second circuit 141. The first via 113 and the second via 142 can be electrically connected with each other.

A thickness of the polymer layer 140 can be smaller than that of the ceramic layer 110, and can be about 12 um. The polymer layer 140 can include polyimide, which is chemically stable and solid and thus can improve the durability of a substrate.

The via electrode 150 can be formed by penetrating the polymer layer 140 and can be connected with the capacitor 130. One surface of the via electrode 150 can be exposed, and the other surface of the via electrode 150 can be in contact with the external electrode 132 of the capacitor 150. The capacitor 130 can be charged to have electric charge and discharged to release electric charge. The via electrode 150 can be a path for releasing the electric charge. The via electrode 150 can be made of copper (Cu).

In the case where the polymer layer 140 includes a plurality of layers, the via electrode 150 can penetrate all of the plurality of layers and can be formed perpendicularly to the polymer layer 140. Accordingly, the capacitor 130 can supply electric charge through the relatively short via electrode 150, thereby reducing the generation of noise.

In the case where the depth of the receiving groove 120 is greater than the thickness of the capacitor 130, the resin material 121 filled in the receiving groove 120 can cover the upper surface of the capacitor 130. Here, the via electrode 150 can be formed to penetrate all of the polymer layer 140 and the resin material 121.

The pad electrode 160 can be formed on an upper surface of the polymer layer 140 so as to be connected with the via electrode 150. The pad electrode 160 can function as a terminal for electrical connection with an external circuit.

The pad electrode 160 can be varied depending on the number of capacitors 130, and as shown in FIG. 1, two pad electrodes 160 can be formed for each capacitor 130. The pad electrode 160 can be made of copper (Cu).

Formed on an opposite surface of the surface of the ceramic layer 110 where the receiving groove 120 is formed can be a first pad 114, which can be electrically connected with the first circuit 112 and the first via 113.

The capacitor embedded substrate 100 in accordance with an embodiment of the present invention can be used in a probe card. In such a case, the first pad 114 can be electrically connected with the PCB of the probe card, and second pad 143 can be electrically connected with a semiconductor wafer. As a contact pad of the semiconductor wafer is minute, the second pad 143 can be formed in such a way that a pitch thereof is smaller than that of the first pad 114.

Referring to FIG. 2, in the capacitor embedded substrate 100 in accordance with another embodiment of the present invention, the receiving groove 120 can be formed in such a way that the depth thereof is the same as the thickness of the capacitor 130. In such a case, the resin material 121 can be interposed between a side surface of the capacitor 130 and the inside wall of the receiving groove 120.

Referring to FIG. 3, in the capacitor embedded substrate 100 in accordance with yet another embodiment of the present invention, the receiving groove 120 can be formed in such a way that the depth thereof is smaller than the thickness of the capacitor 130. In such a case, a lower portion of the capacitor 130 can be received in the receiving groove 120, and an upper portion in the polymer layer 140, and the via electrode 150 becomes shorter by the thickness of the upper portion of the capacitor 130 that is received in the polymer layer 140, thereby resulting in a noise reduction effect.

As described above, according to the capacitor embedded substrate in accordance with certain embodiments of the present invention, the capacitor can be readily embedded in the substrate. The embedded capacitor can reduce the noise when the electric charge is supplied from the capacitor. Moreover, since the capacitor is embedded at a boundary portion of the ceramic layer and polymer layer, the capacitor can be readily replaced.

Hitherto, the capacitor embedded substrate in accordance with certain embodiments of the present invention has been described. Hereinafter, a method of manufacturing a capacitor embedded substrate will be described.

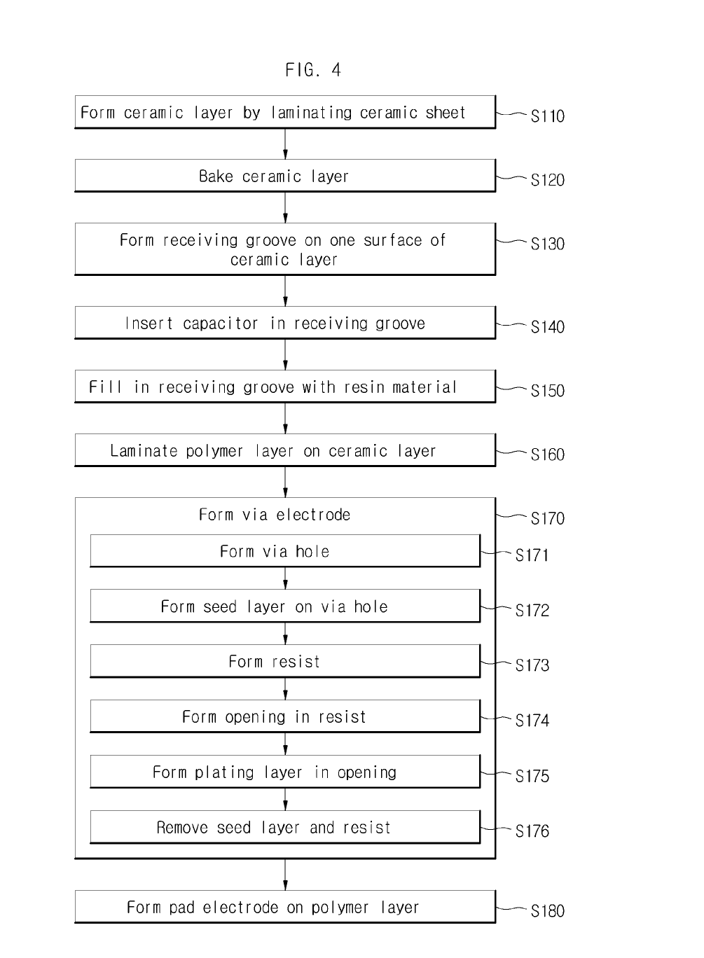

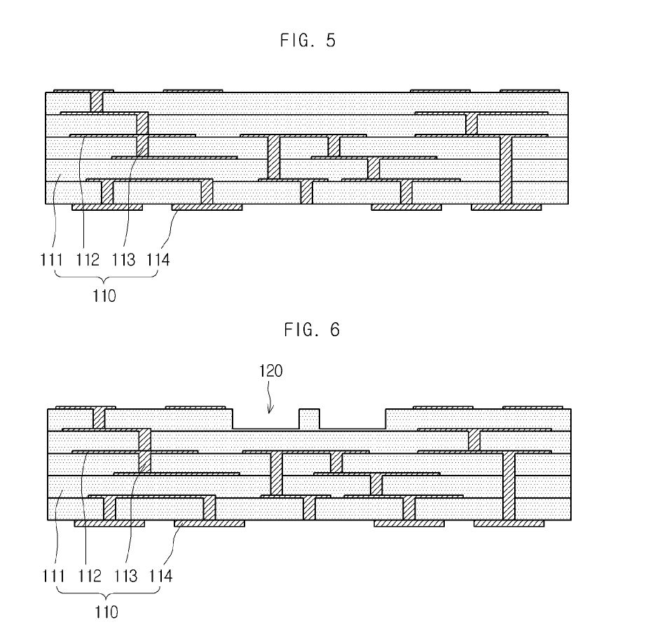

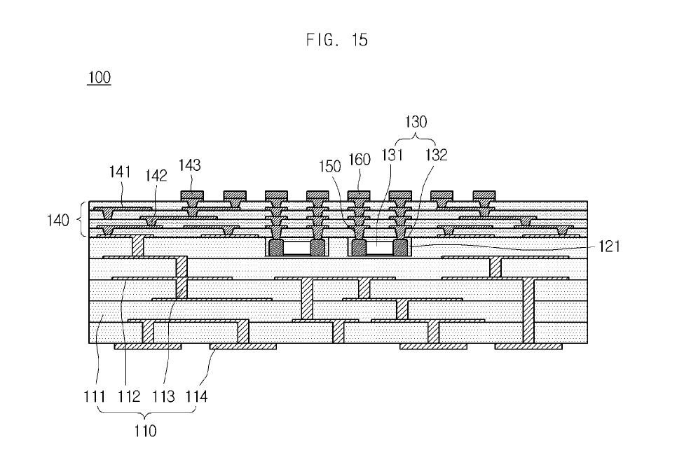

FIG. 4 is a flow diagram showing a method of manufacturing a capacitor embedded substrate in accordance with an embodiment of the present invention, and FIGS. 5 to 15 show processes for the method of manufacturing a capacitor embedded substrate in accordance with an embodiment of the present invention.

Referring to FIG. 4, the method of manufacturing a capacitor embedded substrate in accordance with an embodiment of the present invention can include: forming a ceramic layer 110 by laminating a ceramic sheet 111 (S110); baking the ceramic layer 110 (S120); forming a receiving groove 120 on one surface of the ceramic layer 110 (S130); inserting a capacitor 130 in the receiving groove 120 (S140); filling in the receiving groove 120 with a resin material 121 (S150); laminating a polymer layer 140 on the ceramic layer 110 (S160); forming a via electrode 150 (S170); and forming a pad electrode 160 (S180).

Referring to FIG. 5, in the step of forming the ceramic layer 110 by laminating the ceramic sheet 111 (S110), a plurality of ceramic sheets 111 are laminated to form the ceramic layer 110. The ceramic layer 110 can be constituted with 60 to 80 ceramic sheets 111. In such a case, each ceramic sheet 111 can have a first circuit 112 and a first via 113 formed therein.

In the step of baking the ceramic layer 110 (S120), the ceramic layer 110 is baked in a high-temperature environment. In the case of LTCC, the ceramic layer 110 can be baked at 850° C. to 1000° C., and in the case of HTCC, the ceramic layer 110 can be baked at 1700° C. When the ceramic layer 110 is baked, the ceramic layer 110 becomes contracted as well as solid.

Referring to FIG. 6, in the step of forming the receiving groove 120 on one surface of the ceramic layer 110 (S130), the receiving groove 120 is formed using laser or drill on one surface of the ceramic layer 110. The receiving groove 120 is formed on an inside of the ceramic layer 110 can be provided in plurality.

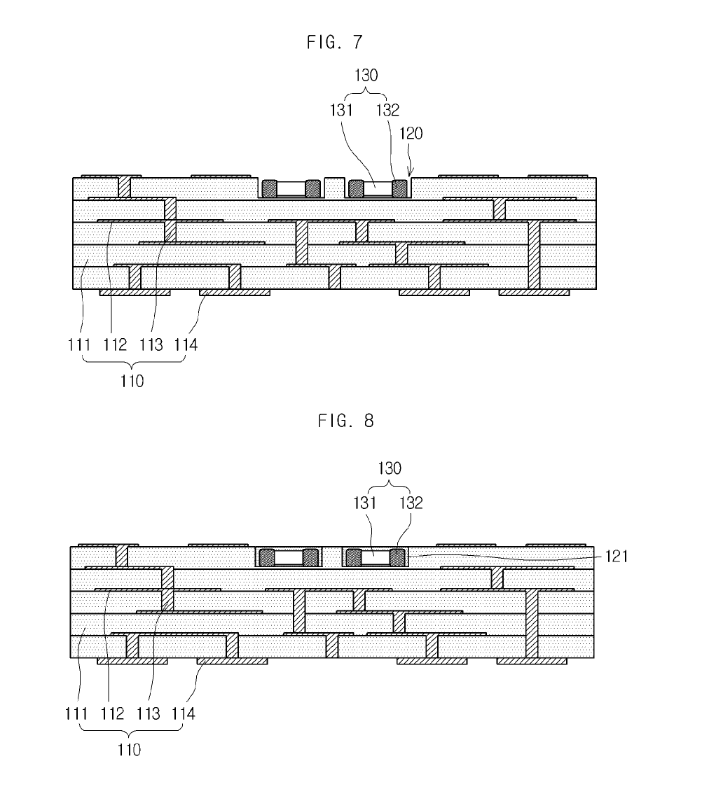

Referring to FIG. 7, in the step of inserting the capacitor 130 in the receiving groove 120 (S140), the capacitor 130 is inserted in the receiving groove 120 that is formed on the ceramic layer 110. Although it is illustrated in FIG. 7 that a depth of the receiving groove 120 is greater than a thickness of the capacitor 130, the depth of the receiving groove 120 can be the same as or smaller than the thickness of the capacitor 130, if necessary.

Referring to FIG. 8, in the step of filling in the receiving groove 120 with the resin material 121 (S150), the receiving groove 120 is filled in with the resin material 121 in order to fix the capacitor 130. The step of filling in the receiving groove 120 with the resin material 121 (S150) can be carried out before or after the step of inserting the capacitor 130 in the receiving groove 120 (S140).

The resin material 121 functions to fix the capacitor 130, which can be inserted in the receiving groove 120 in such a way that the capacitor 130 is spaced from an inside wall of the receiving groove 120. The resin material 121 can be filled in a spaced gap between the capacitor 130 and the receiving groove 120.

The resin material 121 can cover an upper surface of the capacitor 130. The resin material 121 can include polyimide. The resin material 121 can be ground after being filled in so that a surface thereof becomes flat.

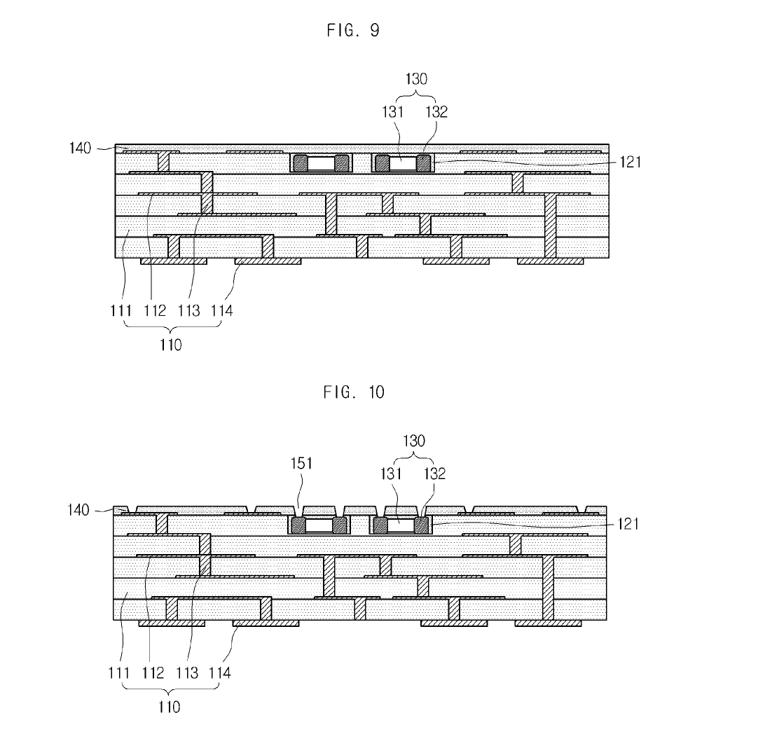

Referring to FIG. 9, in the step of laminating the polymer layer 140 on the ceramic layer 110 (S 160), the polymer layer 140 is formed on the ceramic layer 110 in order to embed the capacitor in the receiving groove 120. The polymer layer 140 can include a second circuit 141 and a second via 142, and the second circuit 141 and the second via 142 can be electrically connected with the first circuit 112 and the first via 113.

In the step of forming the via electrode 150 (S170), the polymer layer 140 is penetrated to form the via electrode 150, which is electrically connected with the capacitor 130. The via electrode 150 can be made of copper.

In the case where the depth of the receiving groove 120 is greater than the thickness of the capacitor 130, the resin material 121 can cover the upper surface of the capacitor 130, and the via electrode 150 can penetrate the resin material 121.

The step of forming the via electrode 150 (S170) can include: forming a via hole 151 (S171); forming a seed layer 152 on the via hole 151 (S172); forming a resist 153 (S173); forming an opening 154 in the resist 153 (S174); forming a plating layer 155 in the opening 154 (S175); and removing the seed layer 152 and the resist 153 (S176).

Referring to FIG. 10, in the step of forming the via hole 151 (S171), a hole is formed in the polymer layer 140 by use of laser or drill so that an external electrode 132 of the capacitor 130 is exposed. Once the resin material 121 covers the upper surface of the capacitor 130, the via hole 151 can penetrate the resin material 121. The via electrode 150 can be formed by having a conductor formed in the via hole 151.

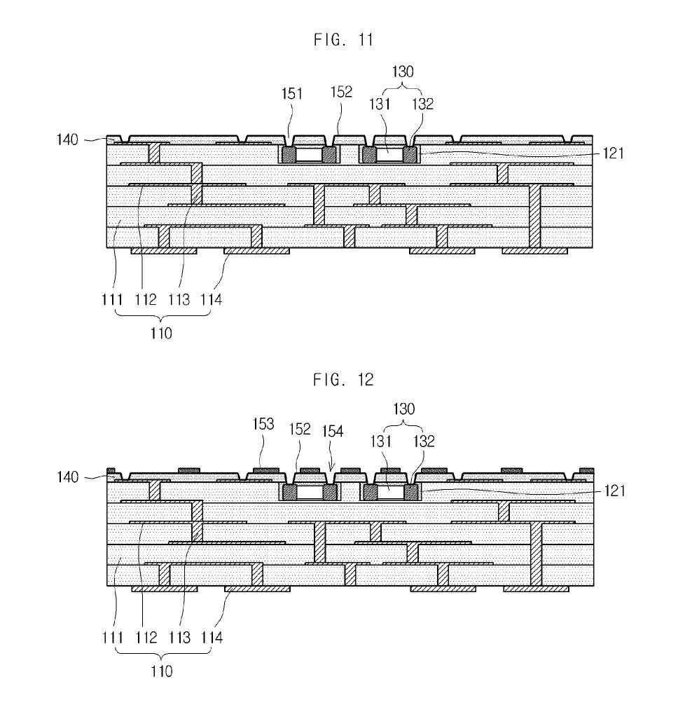

Referring to FIG. 11, in the step of forming the seed layer 152 on the via hole 151 (S172), the seed layer 152 for plating is formed on the via hole 151. The seed layer 152 can be formed on the ceramic layer 110 as well. The seed layer 152 can be made of the same material as that of the via electrode 150, for example, copper.

In the step of forming the resist 153 (S173), the resist 153 is formed on the seed layer 152. The resist can be photoresist.

Referring to FIG. 12, in the step of forming the opening 154 in the resist 153 (S174), a portion of the resist 153 is removed through exposure and development processes. The opening 154 can be formed to correspond to a position of the via electrode 150.

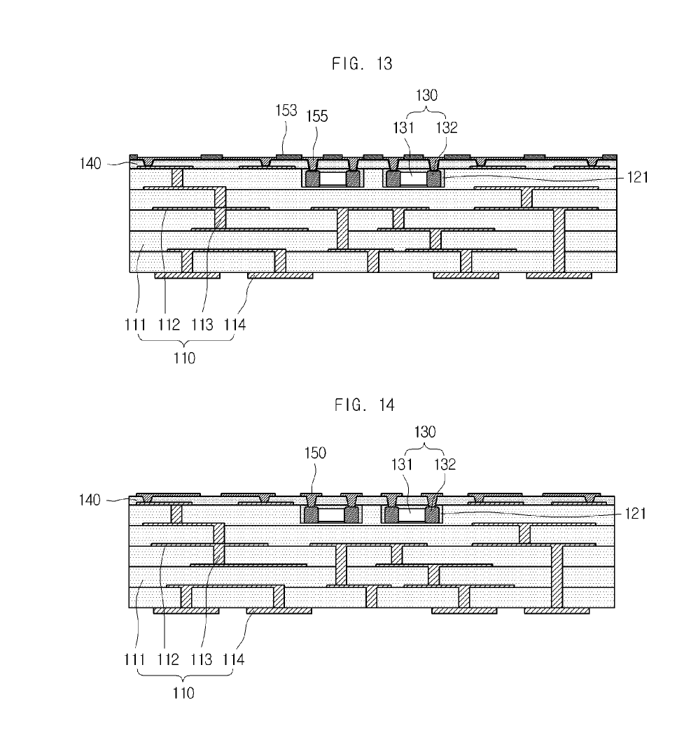

Referring to FIG. 13, in the step of forming the plating layer 155 in the opening 154 (S175), an inner portion of the opening 154 is plated. The plating layer 155 can be made of the same material as that of the seed layer 152.

Referring to FIG. 15, in the step of removing the seed layer 152 and the resist 153 (S176), the remaining seed layer 152 and resist 153 are removed to leave the plating layer 155 only. The plating layer 155 becomes the via electrode 150.

As shown in FIG. 15, the polymer layer 140 can be formed through a build-up process of a plurality of insulating layers.

Referring to FIG. 15, in the step of forming the pad electrode 160 (S180), the pad electrode 160 is formed on an upper surface of the polymer layer 140 so as to be connected with the via electrode 150. Like the via electrode 150, the pad electrode 160 can be made of copper. The pad electrode 160 can have a bigger cross section than the via electrode 150 and thus can function as a terminal that is in contact with an external circuit.

As described above, the method of manufacturing a capacitor embedded substrate in accordance with an embodiment of the present invention can readily have the capacitor embedded in the substrate. Moreover, as the capacitor is embedded in a boundary portion of the ceramic layer and the polymer layer, the capacitor can be readily replaced.

Although certain embodiments of the present invention have been described hitherto, it shall be appreciated that the present invention can be variously modified and permutated by those of ordinary skill in the art to which the present invention pertains by supplementing, modifying, deleting and/or adding an element without departing from the technical ideas of the present invention, which shall be defined by the claims appended below. It shall be also appreciated that such modification and/or permutation are also included in the claimed scope of the present invention.

What is claimed is:

1. A capacitor embedded substrate comprising:
a ceramic layer having a first circuit included therein;
a receiving grooved formed on one surface of the ceramic layer;
a capacitor being inserted in the receiving groove;
a polymer layer being laminated on the ceramic layer in such a way that the capacitor is embedded in the receiving groove and comprising a second circuit electrically connected with the first circuit; and
a via electrode being connected with the capacitor by penetrating the polymer layer.

2. The capacitor embedded substrate of claim 1, further comprising a resin material being filled in the receiving groove so as to fix the capacitor.

3. The capacitor embedded substrate of claim 2, wherein the resin material covers an upper surface of the capacitor, and the via electrode penetrates the resin material.

4. The capacitor embedded substrate of claim 1, wherein the receiving groove is formed in such a way that a depth thereof is smaller than a thickness of the capacitor.

5. The capacitor embedded substrate of claim 1, wherein the polymer layer comprises a plurality of layers, and
wherein the via electrode penetrates the plurality of layers perpendicularly to the polymer layer.

6. The capacitor embedded substrate of claim 1, further comprising a pad electrode formed on an upper surface of the polymer layer so as to be connected with the via electrode.

7. The capacitor embedded substrate of claim 1, wherein the polymer layer is formed in such a way that a thickness thereof is smaller than a thickness of the ceramic layer.

8. The capacitor embedded substrate of claim 1, wherein the receiving groove is arranged on an inside of the ceramic layer.

9. The capacitor embedded substrate of claim 1, wherein the polymer layer comprises polyimide.

10. A method of manufacturing a capacitor embedded substrate, comprising:
forming a receiving groove on one surface of a ceramic layer, the ceramic layer having a first circuit included therein;
inserting a capacitor in the receiving groove;
laminating a polymer layer on the ceramic layer in order to embed the capacitor in the receiving groove, the polymer layer comprising a second circuit electrically connected with the first circuit; and
forming a via electrode by penetrating the polymer layer, the via electrode being electrically connected with the capacitor.

11. The method of claim 10, further comprising, prior to forming the receiving groove on the ceramic layer:
forming the ceramic layer by laminating ceramic sheets; and
baking the ceramic layer.

12. The method of claim 10, further comprising, before or after inserting the capacitor in the receiving groove, filling in the receiving groove with a resin material.

13. The method of claim 12, wherein, in the step of forming the receiving groove, the receiving groove is formed in such a way that a depth thereof is greater than a thickness of the capacitor, and
wherein, in the step of forming the via electrode, the via electrode penetrates the resin material covering an upper surface of the capacitor.

14. The method of claim 10, wherein, in the step of laminating the polymer layer on the ceramic layer, the polymer layer is formed in such a way that a thickness thereof is smaller than a thickness of the ceramic layer.

15. The method of claim 10, wherein the polymer layer comprises a plurality of layers, and
wherein, in the step of forming the via electrode, the via electrode penetrates the plurality of layers perpendicularly to the polymer layer.

16. The method of claim 10, wherein the forming of the via electrode comprises:
forming a via hole in the polymer layer in such a way that an external electrode of the capacitor is exposed; and
forming a conductor in the via hole.

17. The method of claim 16, wherein the forming of the conductor comprises:
forming a seed layer on the polymer layer so as to cover an inner portion of the via hole;
forming a resist on the seed layer;
forming an opening in the resist in such a way that the seed layer is exposed;
forming a plating layer in the opening; and
removing the seed layer and the resist.

18. The method of claim 10, further comprising, after forming the via electrode, forming a pad electrode on an upper surface of the polymer layer so as to be connected with the via electrode.
